(19) United States
(12) Patent Application Publication
(10) Pub. No.: US 2007/0066092 A1
(43) Pub. Date: Mar. 22, 2007

(54) Connecting component

(75) Inventor: Kaoru Soeta, Tokyo (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/518,655

(22) Filed: Sep. 11, 2006

(30) Foreign Application Priority Data
Sep. 21, 2005 (JP) 2005-273120

(51) Int. Cl. H05K 1/00

(52) U.S. Cl. 439/67

(57) ABSTRACT

A connecting component is provided. The connecting component includes an elastic contact and a base. The base includes a substrate, a sheet member, and a fixed contact. At least one of the substrate, the sheet member, and the fixed contact is formed using a damping alloy.

### CONNECTING COMPONENT

This application claims the benefit of Japanese Patent Application No. 2005-273120 filed on Sep. 21, 2005, which is hereby incorporated by reference.

### BACKGROUND

1. Field

The present embodiments relate to a connecting component that includes a base and an elastic contact disposed on the base, and particularly, to a connecting component having a high vibration damping property.

2. Related Art

As an example of a conventional contact unit between small-size electronic components, US Publication No. 2002-0037657 and U.S. Pat. No. 6,517,362 (Japanese Unexamined Patent Application Publication No. 2002-175859) disclose a spiral contactor. A spiral contactor is a fine elastic contact unit formed by a thin film technique. Since a contactor of this type applies a small contact pressure, it is expected to be used widely as contact units for small-size electronic components.

A spiral contactor of the above-referenced type can be used as a contact unit for a small-size electronic component incorporated in a portable device, such as a mobile phone.

Generally, in a portable device, there are cases where instantaneous interruption occurs between a connecting component and an electronic component due to vibration caused by an internal vibratory source or external environment. Moreover, in response to such vibration, the connecting component may possibly become displaced from its attachment position in a housing.

In order to solve these problems, it is important that a portable device has a structure that is impervious to vibration. However, neither US Publication No. 2002-0037657 nor U.S. Pat. No. 6,517,362 discloses a specific countermeasure against such vibration.

### SUMMARY

One exemplary object of the present embodiments is to provide a connecting component having a vibration damping property.

The present embodiments provide a connecting component, which includes a base and an elastic contact provided on the base. The elastic contact includes a stationary segment fixed to the base, and an elastic arm segment, which is elastically deformed when coming into contact with an external connection terminal. At least a portion of the base or the elastic contact contains a damping alloy.

The use of damping alloy for the base or the elastic contact contributes to an improvement in the vibration damping property of the connecting component. This implies that the connecting component can absorb (dampen) vibration properly. According to the connecting component of the present embodiment, the above-mentioned conventional problems, such as instantaneous interruption and displacement of the connecting component from its attachment position in a housing, is advantageously obviated.

According to the present embodiment, the base preferably includes a supporting member for securely supporting the stationary segment of the elastic contact, and a substrate to which the supporting member is attached. In this case, the substrate or the supporting member preferably contains the damping alloy.

The vibration damping property of the connecting component can be further improved, whereby problems induced by vibration, such as instantaneous interruption and displacement of the connecting component, is advantageously solved.

According to the present embodiment, a damping alloy layer containing the damping alloy is preferably provided in an area of the elastic arm segment excluding a surface thereof that comes into contact with the external connection terminal. The resistivity of the damping alloy is higher than, for example, copper. The damping alloy is not used for the surface of the elastic arm segment that comes into contact with the external connection terminal, but is used in an area other than the contact surface. As a result, the vibration damping property of the elastic contact can be advantageously improved, and a good conducting property can be attained between the elastic contact and the external connection terminal.

For example, the damping alloy layer is preferably provided on a surface of the elastic arm segment that faces the base.

According to the present embodiment, the damping alloy is preferably a twin-crystal-type damping alloy. Accordingly, this contributes to a further improvement in the vibration damping property.

According to the present embodiment, by using the damping alloy for the base or the elastic contact, the vibration damping property of the connecting component can be enhanced. Accordingly, a connecting component that can effectively absorb (dampen) vibration is achieved.

According to the connecting component of the present embodiment, the conventional problems, such as instantaneous interruption and displacement of the connecting component from its attachment-position in a housing, is advantageously solved.

### BRIEF DESCRIPTION OF THE DRAWINGS

FIG. 1 is an external perspective view of a connecting component according to a first embodiment, as viewed from one direction;

FIG. 2 is an external perspective view of the connecting component shown in FIG. 1, as viewed from an opposite direction;

FIG. 3 is a cross-sectional view taken along line III-III in FIG. 1 and shows an example of how the connecting component is used;

FIG. 4 is a partial vertical-sectional view of a connecting component according to a second embodiment;

FIG. 5 is a partial vertical-sectional view of a connecting component according to a third embodiment;

FIG. 6 is a partial vertical-sectional view of a connecting component according to a fourth embodiment; and

FIG. 7 is a partial vertical-sectional view of another example of an elastic contact.

### DESCRIPTION OF THE PREFERRED EMBODIMENTS

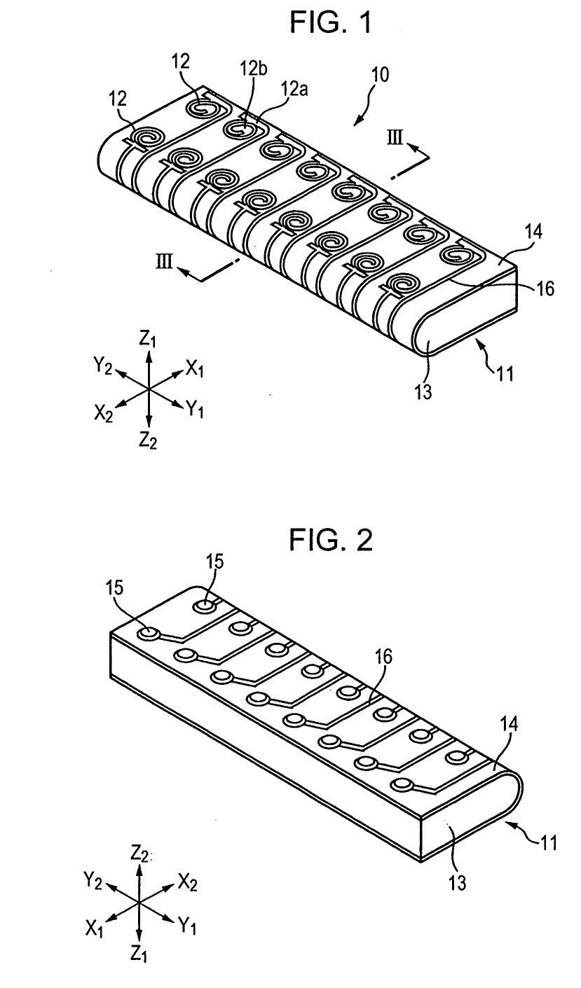

Referring to FIGS. 1 and 2, a connecting component 10 according to a first embodiment has a shape of a bar that extends linearly in directions Y1 and Y2. The connecting component 10 includes a base 11 and elastic contacts 12.

The term “base” in this specification broadly refers to sections of the connecting component 10 that exclude the elastic contacts 12. Moreover, with regard to relationships among X1-X2 direction, Y1-Y2 direction, and Z1-Z2 direction shown in the drawings, each direction is perpendicular to the two remaining directions.

Referring to FIGS. 1 to 3, the base 11 includes a substrate 13, a sheet member (supporting member) 14 adhered to the substrate 13 from an upper surface 13a to a lower surface 13b of the substrate 13, and fixed contacts 15 attached to the lower surface 13b of the substrate 13 with the sheet member 14 interposed therebetween. The fixed contacts 15 are, for example, spherical contacts (BGA: ball grid array) or planar contacts (LGA: land grid array). The shape of the first push switch 15 is not specifically limited.

As shown in FIGS. 1 and 2, the substrate 13 is bar-shaped, and at least one side surface thereof in the width direction (X1-X2 direction) is an arc-shaped curved surface 13c.

Both the elastic contacts 12 and the fixed contacts 15 are attached to the front face of the sheet member 14.

Referring to FIGS. 1 to 3, the elastic contacts 12 disposed on the upper surface 13a of the substrate 13 are electrically connected to the fixed contacts 15 disposed on the lower surface 13b of the substrate 13 via conductor segments 16 provided on the front face of the sheet member 14.

The elastic contacts 12 according to the first embodiment are spiral contacts that have, for example, a helical or spiral shape. The elastic contacts 12 each have a stationary segment 12a and an elastic arm segment 12b that extend from the stationary segment 12a.

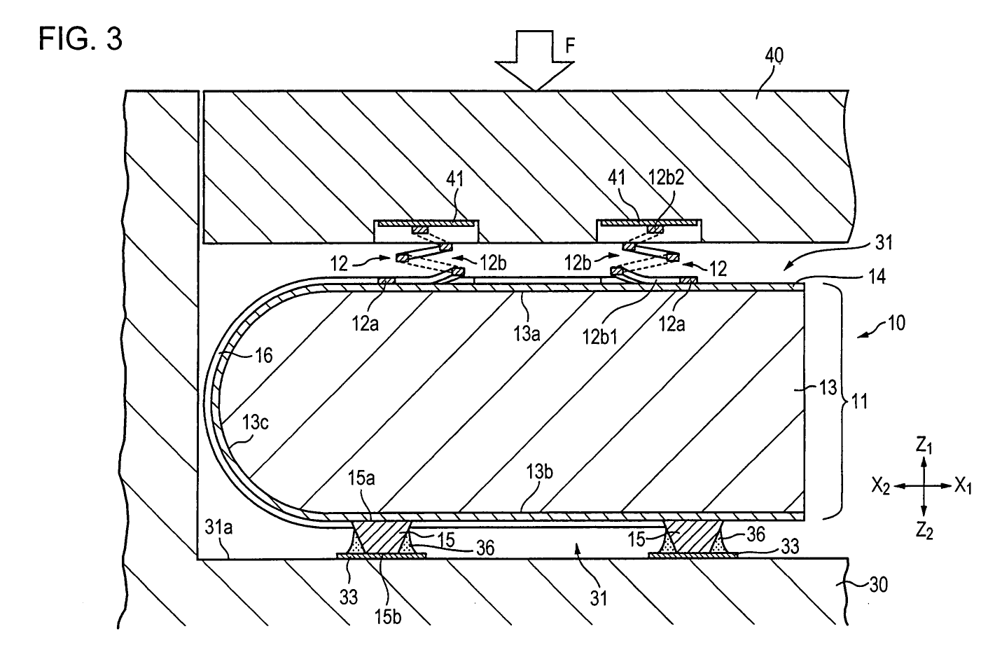

As shown in FIG. 3, each elastic arm segment 12b has a spiral shape from a first spiral end 12b1 to a second spiral end 12b2, and extends gradually in the Z1 direction such that the entire elastic arm segment 12b is given a triangular or gibbous shape. In each elastic contact 12, the elastic arm segment 12b is supported by the stationary segment 12a in a cantilever fashion such that the elastic arm segment 12b is elastically deformable in the Z1 direction with respect to the first spiral end 12b1 as being a supporting point. Therefore, the elastic arm segment 12b is entirely elastically deformable in the Z1 and Z2 directions.

The stationary segment 12a included in each elastic contact 12 is attached to the front face of the sheet member 14 with, for example, a conductive adhesive.

The connecting component 10 according to the first embodiment is generally used for attaining an electrical connection with electrodes of an electronic component. For example, the connecting component 10 serves as a contact electrode unit for connecting external connection terminals provided in a device body to external connection terminals exposed on a surface of a memory card detachable to the device body. Alternatively, by setting an array of a plurality of the connecting components 10, the connecting components 10 can serve as a contact electrode unit connectable to external connection terminals, such as BGA or LGA, disposed on a bottom surface of an IC package.

FIG. 3 shows an example in which the connecting component 10 is installed in an installation section 31 provided in a device body 30 of, for example, a mobile phone. A bottom surface 31a of the installation section 31 is provided with a plurality of external connection terminals (electrodes) 33, 33 that are opposed to the plurality of fixed contacts 15, 15. The fixed contacts 15, 15 of the connecting component 10 are conductively fixed to the external connection terminals 33, 33 of the installation section 31 with a bonding material 36, for example, solder and conductive adhesive.

An upper portion of the installation section 31 serves as a space for housing an electronic component 40, such as a small-size memory card. As shown in FIG. 3, the electronic component 40 is installed in a manner such that external connection terminals (electrodes) 41, 41 thereof face downward.

When a cover (not shown) is closed, the electronic component 40 is pressed in the Z2 direction with a predetermined pressing force F. Thus, the elastic arm segments 12b included in the elastic contacts 12 of the connecting component 10 come into contact with the external connection terminals 41, 41 of the electronic component 40 so as to become elastically deformed in a contracting direction. Consequently, the external connection terminals 41, 41 of the electronic component 40 and the elastic contacts 12 become electrically connected to each other.

Alternatively, the external connection terminals 41 and the elastic contacts 12 may be joined to each other with a bonding material, such as a conductive adhesive. In areas where the external connection terminals 41 and the elastic contacts 12 are not provided, the lower surface of the electronic component 40 may be joined to the upper surface of the base 11 with, for example, an adhesive.

Alternatively, the electronic component 40 may be installed in a detachable state without the use of the bonding material. For example, in response to the pressing force F, an elastic reaction force is generated from the elastic arm segments 12b of the elastic contacts 12 in the upward direction (Z1 direction). Therefore, the connected state between the external connection terminals 41 of the electronic component 40 and the elastic contacts 12 of the connecting component 10 can be properly maintained without the use of the bonding material.

Accordingly, the external connection terminals 41, 41 of the electronic component 40 are electrically connected to the external connection terminals 33, 33 of the device body 30 via the elastic contacts 12, the conductor segments 16, and the fixed contacts 15.

In the first embodiment, the substrate 13 is formed using a damping alloy.

A damping alloy is a type of an alloy that absorbs vibration. There are various types of damping alloys, such as a composite type, a ferromagnetic type, a dislocation type, and a twin-crystal type. In the first embodiment, a damping alloy of a twin-crystal type is preferably used.

When a load is applied to a twin-crystal-type damping alloy, twin crystal is generated, and the generated twin crystal is movable. As the load increases, the already-generated twin crystal increases in width, or new twin crystal is generated in other areas. Due to the generation and movement of the twin crystal, kinetic energy changes to thermal energy, whereby vibration can be absorbed.

The twin crystal disappears when the external load is removed, and the alloy returns to its non-loaded state.

The damping alloy used in the first embodiment needs to at least satisfy both vibration damping capability and moldability. The twin-crystal-type damping alloy mentioned above can properly satisfy both vibration damping capability and moldability by selecting appropriate materials.

A twin-crystal-type damping alloy includes, for example, a Mn—Cu based type, a Cu based type, and a Ti—Ni based type. The damping alloy to be used preferably has Mn as a main component, and, as a basic composition, contains about 15% to 25% of Cu, about 2% to 8% of Ni, about 1% to 3% of Fe, and the remaining percentage of Mn. This allows the logarithmic decrement of the damping alloy to be set within a range of 0.2 to 0.7 and achieves high moldability.

With regard to the moldability, the damping alloy having the above composition can be manufactured in the form of powder or particles. The damping alloy can be mixed in, for example, a plating bath or paste, and the damping alloy can be formed by plating or printing. The damping alloy also allows for, for example, soldering.

Depending on the composition, the damping alloy can be conductive or insulative. Moreover, the damping alloy is extremely close to being nonmagnetic.

For example, as a twin-crystal-type damping alloy, a damping alloy “M2052” manufactured by KABUSHIKI KAISHA SEISIN may be used. The composition of the alloy is Mn_{73at%}, Cu_{20at%}, Ni_{5at%}, and Fe₂ₐₜ%.

In the first embodiment shown in FIGS. 1 to 3, the substrate 13 is formed using the above-referenced damping alloy. The damping alloy is contained in at least a portion of the composition of the substrate 13. The substrate 13 may either be insulative or conductive.

The reason the substrate 13 may be conductive is that the substrate 13, the elastic contacts 12, and the fixed contacts 15 are not directly in contact with each other. However, the substrate 13 is preferably an insulative substrate. If the damping alloy has conductivity, the substrate 13 is preferably formed by mixing an insulating material with the damping alloy so as to enhance the insulation property of the substrate 13.

Alternatively, referring to FIG. 1, in the first embodiment, the damping alloy may be used for the sheet member 14 in place of the substrate 13 or together with the substrate 13. In this case, at least the front face of the sheet member 14 that is in contact with the elastic contacts 12 and the fixed contacts 15 needs to be insulative. Therefore, by adjusting the composition ratio, for example, an insulative sheet member composed of the damping alloy may be formed, or the sheet member 14 may be a laminate having an insulative sheet member (for example, polyimide resin) disposed over a conductive sheet member composed of the damping alloy.

Because the sheet member 14 is adhered to the substrate 13 from the upper surface 13a to the lower surface 13b thereof in a folded fashion, the sheet member 14 needs to be flexible.

In the first embodiment shown in FIGS. 1 to 3, the substrate 13 and/or the sheet member 14 is/are formed using the damping alloy so that the vibration damping property of the base 11 is enhanced. Because the substrate 13 and the sheet member 14 occupy a large volume of the base 11 and extend over a large area, the vibration damping property of the base 11 can be effectively improved.

Sections of the base 11 other than the substrate 13 and the sheet member 14, such as the fixed contacts 15 and the conductor segments 16, may be formed using the above-referenced damping alloy. In this case, only the fixed contacts 15 or only the conductor segments 16 may contain the above-referenced damping alloy, but since the fixed contacts 15 and the conductor segments 16 do not occupy a large volume of the base 11, it is preferable that the substrate 13 and/or the sheet member 14 be formed using the damping alloy in order to properly improve the vibration damping property of the base 11.

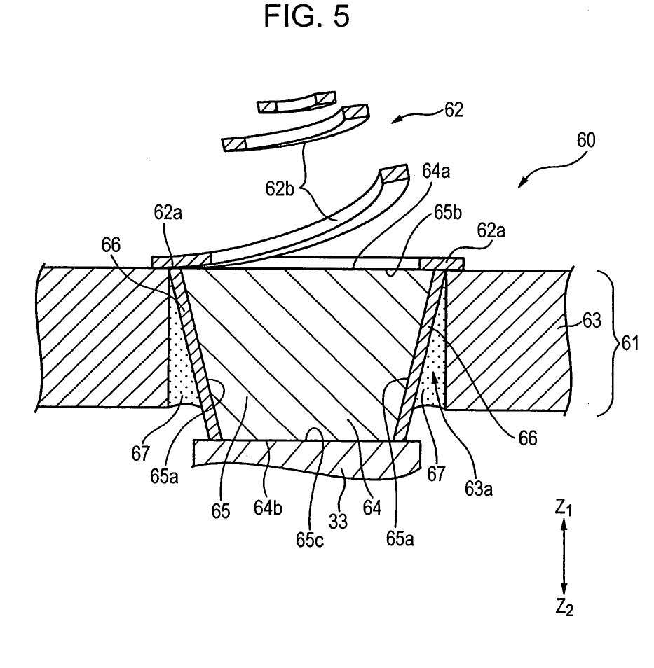

If the fixed contacts 15 were to be formed using the damping alloy, the conductivity of the fixed contacts 15 may deteriorate if the fixed contacts 15 are entirely formed using the damping alloy. Therefore, at least the side surfaces of the damping alloy layer are preferably plated with conductive layers having higher conductivity than the damping alloy layer, such that the external connection terminals 33 and the conductor segments 16 are connected via the conductive layers (see also FIG. 5, which will be described later).

In each fixed contact 15, the damping alloy layer may be partly exposed on an upper surface 15a and a lower surface 15b of the fixed contact 15. The lower surface 15b of the fixed contact 15 is connected to the corresponding external connection terminal 33, and the damping alloy layer partly exposed on the lower surface 15b of the fixed contact 15 allows for the damping alloy layer to be properly soldered to the external connection terminal 33.

In the first embodiment shown in FIGS. 1 to 3, the fixed contacts 15 may alternatively be elastic contacts.

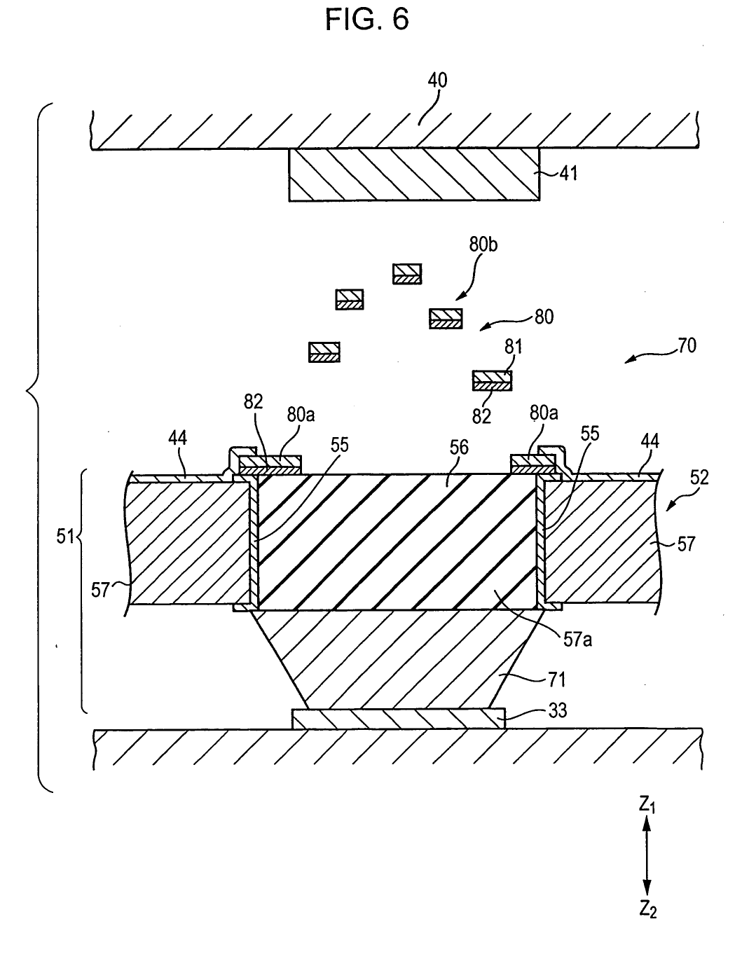

In the first embodiment shown in FIGS. 1 to 3, the damping alloy may be used in at least a portion of each of the elastic contacts 12 in addition to the substrate 13 and/or the sheet member 14 or instead of being used in the substrate 13 and the sheet member 14. An embodiment in which a damping alloy is used in at least a portion of each elastic contact 12 will be described later in another embodiment with reference to FIG. 6.

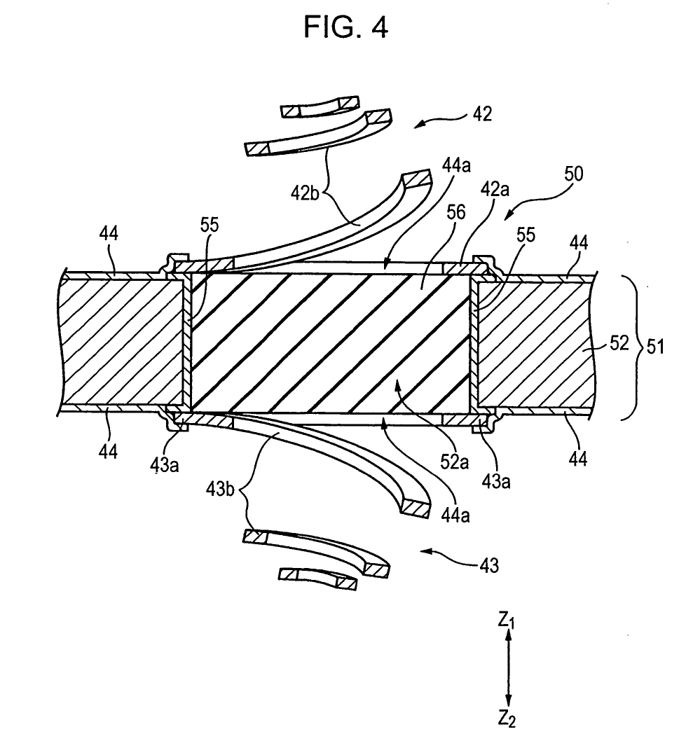

FIG. 4 is a partial vertical-sectional view of a connecting component 50 according to a second embodiment, which has at least a structure different from that of the connecting component 10 according to the first embodiment shown in FIGS. 1 to 3.

The connecting component 50 includes a base 51, upper elastic contacts 42 disposed on an upper surface of the base 51, and lower elastic contacts 43 disposed on a lower surface of the base 51. Similar to the elastic contacts 12 illustrated in FIG. 3, the upper elastic contacts 42 each have a stationary segment 42a and an elastic arm segment 42b extending three-dimensionally and spirally from the stationary segment 42a. The lower elastic contacts 43 each have a stationary segment 43a and an elastic arm segment 43b extending three-dimensionally and spirally from the stationary segment 43a.

The base 51 includes a substrate 52 and sheet members 44, 44.

The substrate 52 is provided with through holes 52a at positions where the elastic arm segments 42b, 43b of the upper elastic contacts 42 and the lower elastic contacts 43 are opposed to each other in the height direction (Z1-Z2 direction). Each of the through holes 52a is provided with a conductor portion 55 on a side wall thereof. Moreover, each of the through holes 52a also has an insulating layer 56 implanted therein. The insulating layer 56 may be omitted where necessary.

The sheet members 44 securely support the elastic contacts 42, 43 via the stationary segments 42a, 43a. The sheet members 44 are provided with through holes 44a at positions where the elastic arm segments 42b, 43b are opposed to each other. The elastic arm segments 42b, 43b extend away from the base 51 from the corresponding through holes 44a.

Referring to FIG. 4, the sheet member 44 that securely supports the stationary segment 42a of each upper elastic contact 42 is adhered to an upper surface of the substrate 52 with, for example, an anisotropic conductive adhesive (not shown). The stationary segment 42a of the upper elastic contact 42 and the conductor portion 55 are electrically connected to each other via the anisotropic conductive adhesive.

The sheet member 44 that securely supports the stationary segment 43a of each lower elastic contact 43 is adhered to a lower surface of the substrate 52 with, for example, an anisotropic conductive adhesive (not shown). The stationary segment 43a of the lower elastic contact 43 and the conductor portion 55 are electrically connected to each other via the anisotropic conductive adhesive.

The upper elastic contact 42 and the lower elastic contact 43 are electrically connected to each other via the conductor portion 55.

In the second embodiment shown in FIG. 4, the substrate 52 and/or the sheet members 44 is/are formed using the above-referenced damping alloy.

Since both the sheet members 44 and the substrate 52 need to be insulative, the composition ratio of the alloy is adjusted so that an insulative damping alloy is used for the sheet members 44 and/or the substrate 52.

In the second embodiment shown in FIG. 4, the insulating layer 56 and the conductor portion 55 may also contain the damping alloy.

One of the upper elastic contacts 42 and the lower elastic contacts 43 may alternatively be a fixed contact. For example, the lower elastic contact 43 may alternatively be a fixed contact similar to the fixed contact 15 shown in FIG. 3. In this case, the fixed contact may be formed using the damping alloy or may be not formed using the damping alloy.

FIG. 5 is a partial vertical-sectional view of a connecting component 60 according to a third embodiment, which has a structure different from those of the connecting components 10, 50 shown in FIG. 1 to 4.

The connecting component 60 includes a base 61 and elastic contacts 62 disposed on an upper surface of the base 61. Similar to the elastic contacts 12 illustrated in FIG. 3, the elastic contacts 62 each have a stationary segment 62a and an elastic arm segment 62b extending three-dimensionally and spirally from the stationary segment 62a. The base 61 includes a substrate 63 and fixed contacts 64.

The substrate 63 is provided with through holes 63a at positions facing the elastic arm segments 62b of the elastic contacts 62 in the height direction (Z1-Z2 direction).

The fixed contacts 64 are fitted in the corresponding through holes 63a. An upper surface 64a of each fixed contact 64 has the stationary segment 62a of one of the elastic contacts 62 adhered thereon with a conductive adhesive (not shown). Thus, the elastic contact 62 and the fixed contact 64 are electrically connected to each other. A lower surface 64b of each fixed contact 64 is projected downward from the lower surface of the substrate 63.

In the third embodiment shown in FIG. 5, a bonding layer 67 composed of, for example, anisotropic conductive paste (ACP) or non-conductive paste (NCP) is injected into a gap between each through hole 63a and the corresponding fixed contact 64, and is hardened by heat curing so that the fixed contact 64 is secured within the through hole 63a.

Alternatively, without the use of the bonding layer 67, the fixed contact 64 may be press-fitted to the through hole 63a of the substrate 63.

In the third embodiment shown in FIG. 5, the substrate 63 is formed using the above-referenced damping alloy. The substrate 63 needs to be insulative.

The fixed contacts 64 may also be formed, for example, using the damping alloy. Forming at least the substrate 63 that occupies a significantly large volume of the base 61 using the damping alloy effectively contributes to an improved vibration damping property of the base 61 rather than using the damping alloy only for the fixed contacts 64 in the base 61.

If each of the fixed contacts 64 were to be formed using the damping alloy, the fixed contact 64 needs to be conductive. As shown in FIG. 5, it is preferable that at least side surfaces 65a of a damping alloy layer 65 composed of damping alloy be coated with conductive layers 66 having higher conductivity than the damping alloy layer 65 by, for example, plating.

Because the damping alloy layer 65 has lower conductivity than, for example, copper, the conductive layers 66 having higher conductivity than the damping alloy layer 65 are formed on at least the side surfaces 65a of the damping alloy layer 65. The conductive layers 66 electrically connect the elastic contact 62 and the external connection terminal (electrode) 33 connected to the fixed contact 64. Thus, an electric current flows properly from the elastic contact 62 to the external connection terminal 33, whereby a good electric property is attained.

An upper surface 65b and a lower surface 65c of the damping alloy layer 65 may also have the conductive layers 66 formed thereon. In that case, because the damping alloy layer 65 can be soldered to another material, if the fixed contact 64 and the external connection terminal 33 are to be joined to each other by soldering, at least a portion of the lower surface 65c of the damping alloy layer 65 (i.e. a surface of the damping alloy layer 65 that faces the external connection terminal 33) is preferably exposed.

As shown in FIG. 5, the lower surface 64b of the fixed contact 64 may alternatively be provided with an elastic contact in a manner such that an elastic arm segment of the elastic contact is connected to the external connection terminal 33.

The third embodiment, which is shown in FIG. 5, is not provided with one or more sheet members for securely supporting the stationary segments of the elastic contacts, but may alternatively be provided with the one or more sheet members. In a case where the one or more sheet members are provided, the substrate 63 and/or the one or more sheet members is/are preferably formed using the above-referenced damping alloy.

FIG. 6 is a partial vertical-sectional view of a connecting component 70 according to a fourth embodiment.

The connecting component 70 according to the fourth embodiment, shown in FIG. 6, has fixed contacts 71 in place of the lower elastic contacts 43 shown in FIG. 4. In FIG. 6, elements equivalent to those in FIG. 4 are given the same reference numerals as those in FIG. 4.

In the fourth embodiment, at least a portion of each of elastic contacts 80 is formed using a damping alloy. Each elastic contact 80 has a stationary segment 80a and an elastic arm segment 80b extending from the stationary segment 80a. The elastic arm segment 80b has a spiral shape from a first spiral end to a second spiral end thereof, and extends gradually to form a gibbous shape.

As shown in FIG. 6, the stationary segment 80a is securely supported by the sheet member 44. The sheet member 44 is adhered to the upper surface of the substrate 52 with, for example, a conductive adhesive. The stationary segment 80a is electrically connected to the conductor portion 55 in the substrate 52. Thus, the elastic contact 80 and the fixed contact 71 are electrically connected to each other via the conductor portion 55.

In the fourth embodiment, the elastic contact 80 has a double layer structure. An upper layer 81 of the double-layer elastic contact 80 has a function of the elastic contact in the other embodiments and is formed of a foil or plating.

The upper layer 81 is composed of, for example, Cu, Ni, and/or Ni—P. For example, the upper layer 81 is formed by electroless plating Ni or Ni—P alloy around Cu. The Ni or Ni—P alloy has higher yield point and elastic modulus than those of Cu. A highly conductive layer composed of, for example, Au may be formed around the Ni or Ni—P alloy by electroless plating.

A lower layer 82 of the double-layer elastic contact 80, which is disposed below the upper layer 81 and faces the base 51, is a damping alloy layer composed of damping alloy. The damping alloy layer is formed by, for example, plating or screen printing. Originally, the elastic arm segment 80b of the elastic contact 80 is not three dimensional as in FIG. 6. Instead, the elastic contact 80 is first formed into a planar shape, and the elastic arm segment 80b is then formed three-dimensionally using a jig. When the elastic arm segment 80b is planar, the damping alloy layer 82 is formed by, for example, plating or screen printing.

As shown in FIG. 6, the damping alloy layer 82 is not provided on a contact side (upper side) of the elastic arm segment 80b that comes into contact with the corresponding external connection terminal 41 of the electronic component 40, but is provided on the underside of the elastic arm segment 80b.

Consequently, the external connection terminal 41 does not come into contact with the damping alloy layer 82. The damping alloy layer 82 has higher resistivity than, for example, copper. In order to attain a good conducting property with respect to the external connection terminal 41, it is preferable that the damping alloy layer 82 be disposed at a section other than the contact side (upper side) that comes into contact with the external connection terminal 41 of the electronic component 40.

As shown in FIG. 6, if the damping alloy layer 82 is to be disposed at a section other than the contact side (upper side) that comes into contact with the external connection terminal 41 of the electronic component 40, the damping alloy layer 82 may be insulative instead of being conductive.

Since the stationary segment 80a also has a double layer structure in the fourth embodiment shown in FIG. 6, the damping alloy layer 82 is in contact with the conductor portion 55. Because the damping alloy layer 82 has high resistivity, it is preferable that, when forming the damping alloy layer 82, a resist, for example, be used so that the damping alloy layer 82 is formed only on the elastic arm segment 80b and not on the stationary segment 80a.

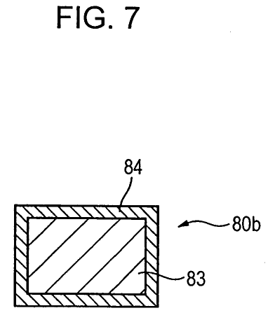

FIG. 7 is a partial vertical-sectional view showing another example of the elastic contact 80. As shown in FIG. 7, an auxiliary elastic layer 84 is formed around a damping alloy layer 83 by electroless plating so as to cover the upper, lower, and side surfaces of the damping alloy layer 83.

The auxiliary elastic layer 84 is composed of a material that has higher yield point and elastic modulus than the damping alloy layer 83. For example, the auxiliary elastic layer 84 is preferably composed of Ni or Ni—X (where X being at least one of P, W, Mn, Ti, and Be).

The auxiliary elastic layer 84 may be coated with a conductive layer, which has lower resistivity than the auxiliary elastic layer 84 and is composed of Cu, Au, Ag, Pd, or Cu alloy.

In the example shown in FIG. 7, the damping alloy layer 83 is provided at a section other than the contact side (upper side) of the elastic arm segment 80b that comes into contact with the corresponding external connection terminal 41 of the electronic component 40. Accordingly, a good conducting property can be attained between the external connection terminal 41 and the elastic contact 80.

In each of the above embodiments shown in FIGS. 1 to 6, at least one of the elastic contacts, the sheet member(s), and the substrate may contain the damping alloy. Accordingly, vibration can be properly absorbed by the base and the elastic contacts, whereby a connecting component having a high vibration damping property is achieved.

Since the sheet members and the substrate included in the base occupy a large volume of the base and extend over a large area, the use of damping alloy for the sheet members and the substrate contributes to an improvement in the vibration damping property of the base.

The use of damping alloy in at least a portion of each elastic contact contributes to an improvement in the vibration damping effect of the elastic contacts.

When vibration is transmitted to the connecting component, the connecting component can effectively absorb (dampen) the vibration, thereby solving conventional problems such as instantaneous interruption and displacement of the connecting component from its attachment position in a housing. Accordingly, the connecting component according to each of the above embodiments of the present invention can be suitably used in a portable device, such as a mobile phone.

While the invention has been described above by reference to various embodiments, it should be understood that many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention.

What is claimed is:

1. A connecting component comprising:
a base; and
an elastic contact provided on the base, the elastic contact includes a stationary segment fixed to the base, and an elastic arm segment that is elastically deformed when coming into contact with an external connection terminal, wherein at least a portion of the base or the elastic contact contains a damping alloy.

2. The connecting component according to claim 1,
wherein the base further includes a supporting member that securely supports the stationary segment of the elastic contact, and a substrate to which the supporting member is attached, and
wherein at least a portion of the substrate or the supporting member contains the damping alloy.

3. The connecting component according to claim 2,
wherein the substrate or the supporting member is insulative.

4. The connecting component according to claim 2,
wherein at least a portion of the supporting member comprises a flexible sheet, and
wherein the supporting member is adhered to the substrate in a folded fashion.

5. The connecting component according to claim 1,
wherein a damping alloy layer containing the damping alloy is provided in an area of the elastic arm segment that excludes a surface thereof that comes into contact with the external connection terminal.

6. The connecting component according to claim 5,
wherein the damping alloy layer is provided on a surface of the elastic arm segment that faces the base.

7. The connecting component according to claim 6,
wherein the elastic arm segment is provided with an upper layer containing Ni or Ni—P alloy around Cu.

8. The connecting component according to claim 5,
wherein an auxiliary elastic layer containing Ni or Ni—P alloy is disposed around the damping alloy layer.

9. The connecting component according to claim 1,
wherein the base is provided with a fixed contact.

10. The connecting component according to claim 9,
wherein the fixed contact contains the damping alloy, and
wherein the fixed contact is provided with a conductive layer.

11. The connecting component according to claim 1,
wherein the damping alloy comprises a twin-crystal-type damping alloy.
